(19) United States
(12) Patent Application Publication
(10) Pub. No.: US 2009/0263729 A1
(43) Pub. Date: Oct. 22, 2009

(54) TEMPLATES FOR IMPRINT LITHOGRAPHY AND METHODS OF FABRICATING AND USING SUCH TEMPLATES

(75) Inventor: Nishant Sinha, Boise, ID (US)

Correspondence Address: TRASK BRITT, P.C./ MICRON TECHNOLOGY, P.O. BOX 2550, SALT LAKE CITY, UT, 84110, US

(73) Assignee: MICRON TECHNOLOGY, INC., Boise, ID (US)

(21) Appl. No.: 12/106,732

(22) Filed: Apr. 21, 2008

(51) Int. Cl. G03F 1/00; G03F 7/20

(52) U.S. Cl. 430/5; 430/319; 430/322

(57) ABSTRACT

A template for use in imprint lithography is disclosed. The template includes at least two ultraviolet transparent materials bonded together by an ultraviolet transparent epoxy. The ultraviolet transparent epoxy is a polymeric, spin-on epoxy or a two-part, amine-cured epoxy having a viscosity at room temperature of from about 35,000 cps to about 45,000 cps. The template has a substantially uniform index of refraction. Additionally, methods of forming and using the templates are disclosed.

### TECHNICAL FIELD

Embodiments of the invention relate to methods of fabricating and using templates for use in imprint lithography and the templates resulting from the same. More specifically, embodiments of the invention relate to templates having at least two ultraviolet (“UV”) wavelength radiation transparent materials bonded by a UV transparent epoxy.

### BACKGROUND

In the semiconductor industry, conventional patterning processes include patterning a photoresist layer by lithographic methods, such as photolithography, electron beam, or X-ray lithography, for mask definition. The pattern on the photoresist layer is subsequently transferred into a hard material in contact with the photoresist layer using a dry etch, wet etch, or lift-off technique. Photolithography is limited to forming features of about 90 nm with a 248 nm light, about 45 nm with a 193 nm light, and from about 25 nm to about 30 nm with a 13.7 nm (extreme ultraviolet (“EUV”)) light. The limitations on the resolution of conventional photolithography are due to the wavelength of radiation used in the process. In addition, photolithographic equipment becomes increasingly expensive as feature sizes become smaller. In contrast, electron beam lithography is capable of creating smaller features, such as features in the tens of nanometers range. With electron beam lithography, the features are generated at an earlier point in time than with conventional lithography. However, electron beam lithography is expensive and very slow.

As feature sizes on semiconductor devices become smaller, imprint lithography has been proposed as a replacement for photolithography. In imprint lithography, a template having a nanoscale pattern is pressed into a film on the semiconductor device. The pattern on the template deforms the film and forms a corresponding or negative image in the film. After removing the template, the pattern in the film is transferred into the semiconductor device. The size of the pattern on the template and of the corresponding features on the semiconductor device are substantially similar. Therefore, unlike photolithographic techniques where a mask or reticle pattern is reduced substantially (for example, 4×) in size when transferred to the surface of a semiconductor device, imprint lithography is considered a “1×” pattern transfer process because it provides no demagnification of the pattern on the template that is transferred to the semiconductor device surface. Templates for use in imprint lithography are known in the art, as described in U.S. Pat. Nos. 6,580,172 to Mancini et al. and 6,517,977 to Resnick et al. To form the high resolution pattern on the template, electron beam mask-making techniques are typically used. However, use of these techniques is undesirable because they are expensive, have low throughput, and are defect ridden.

As described in U.S. Published Patent Application 2006028690 to Sandhu et al, the entire disclosure of which is incorporated herein by reference, a template is typically formed from quartz or other UV transparent material. To provide increased mechanical strength and integrity to the template during the imprinting process, the template is bonded to another UV transparent material using an adhesive composition.

As feature sizes on semiconductor devices approach sub-100 nm, there is a need for a fast, reliable, and cost effective method of making small features. Since imprint lithography is capable of forming small features, it would be desirable to more easily, cheaply, and reproducibly produce templates for use in imprint lithography.

### BRIEF DESCRIPTION OF THE SEVERAL VIEWS OF THE DRAWINGS

FIG. 1 is a cross-sectional view of a template of the invention,

FIG. 2 is an elevational view of a template of the invention;

FIG. 3 schematically illustrates an embodiment of fabricating the template of FIG. 1;

FIGS. 4 and 5 schematically illustrate an embodiment of fabricating the template of FIG. 1; and

FIGS. 6-8 schematically illustrate using the template of the invention in an imprint lithography process to form features on a substrate.

### DETAILED DESCRIPTION

A template for use in imprint lithography is disclosed. The template includes a high resolution pattern that may be formed by lithography. The pattern on the template provides topography that is used to imprint a pattern of corresponding features on a substrate. As used herein, the term “substrate” means and includes a semiconductor wafer at an intermediate stage in processing. The substrate has already been exposed to at least one processing act, but has yet to undergo additional processing. As such, the template functions as a mold or form to transfer the pattern to the substrate, forming the features on a surface thereof contacted by the template. As described in more detail below, the template may be transparent to UV wavelength radiation. The features formed on the substrate may have dimensions substantially similar to dimensions of the pattern formed on the template. The features may have a feature size or dimension of less than about 100 nm, such as less than about 45 nm. By using photolithographic techniques to form the pattern, the template may be easily and cheaply fabricated. In addition, new infrastructure and processing equipment may not need to be developed because existing photolithographic infrastructure and processing equipment may be used to fabricate the template.

In the following detailed description, reference is made to the accompanying drawings, which form a part hereof, and in which is shown, by way of illustration, specific embodiments in which the invention may be practiced. These embodiments are described in sufficient detail to enable a person of ordinary skill in the an to practice the invention. However, other embodiments may be utilized, and changes may be made, without departing from the scope of the invention. The drawings presented herein are not necessarily drawn to scale and are not actual views of a particular template, fabrication process thereof substrate, or fabrication process thereof but are merely idealized representations that are employed to describe the embodiments of the invention. Additionally, elements common between drawings may retain the same numerical designation.

The following description provides specific details, such as material types and material thicknesses in order to provide a thorough description of embodiments of the invention. However, a person of ordinary skill in the art would understand that the embodiments of the invention may be practiced without employing these specific details. Indeed, the embodiments of the invention may be practiced in conjunction with conventional semiconductor materials employed in the industry. In addition, the description provided below does not form a complete process flow for manufacturing a complete electronic device utilizing the template, and the substrates described below do not form a complete electronic device. Only those process acts and substrates necessary to understand the embodiments of the invention are described in detail below. Additional processing acts to form a complete electronic device from the substrate may be performed by conventional techniques, which are not described herein.

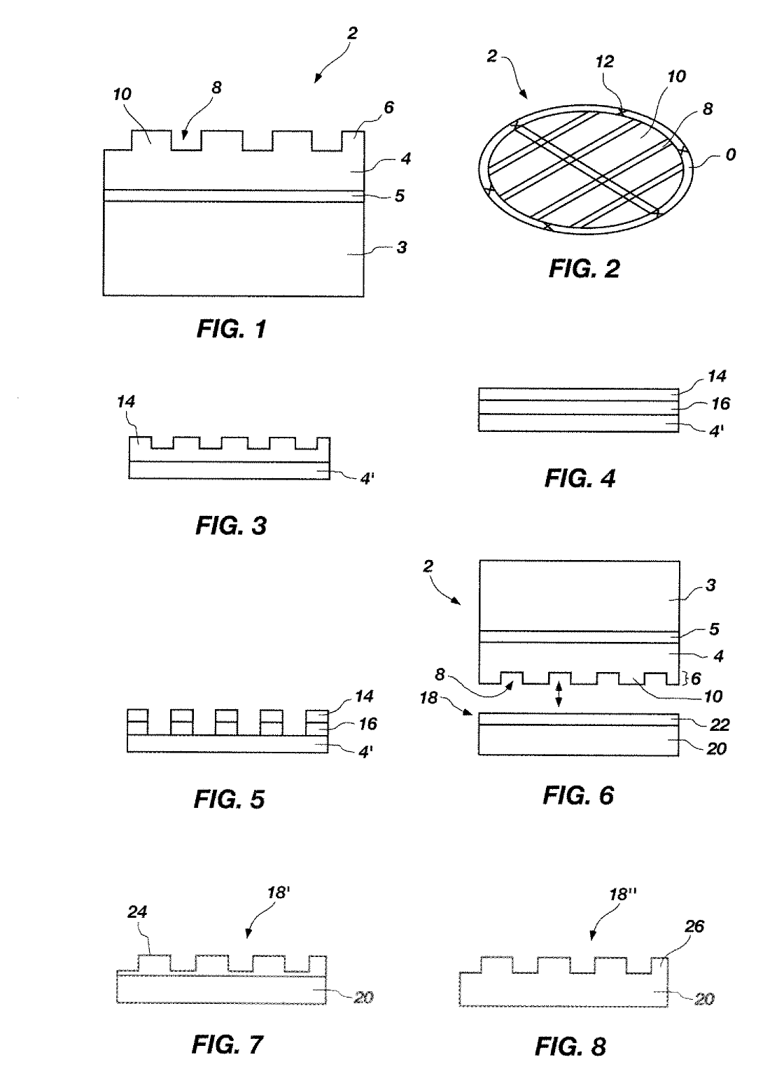

As shown in FIG. 1, template 2 may include at least two UV wavelength radiation transparent (which may also be termed “UV transparent” for convenience) materials 3, 4 that are joined together by a UV transparent epoxy 5. As used herein, the term “epoxy” means and includes a thermoset resin whose chemical reactivity is due to the presence therein of at least one epoxide group or moiety. While FIG. 1 schematically illustrates the UV transparent materials 3, 4 and the UV transparent epoxy 5 as layers, the materials are not limited thereto and may be formed in other configurations. The UV transparent materials 3, 4 may be of substantially the same size and shape and, in the case of a wafer-shaped templates of substantially the same diameter. Thus, the template 2 may have substantially the same dimensions (diameter, etc.) as a conventional semiconductor wafer (silicon wafer) so that processing equipment currently used in photolithography techniques may be used to fabricate the template 2 and so that the template 2 may be used to imprint a pattern on the entire surface of a semiconductor wafer simultaneously. The dimensions of the template 2 may also enable the template 2 to be utilized in a conventional imprint lithography device without further modifications to the template 2 or to the imprint lithography device. However, if the UV transparent materials 3, 4 of the template 2 have smaller or larger dimensions than a conventional semiconductor wafer, the processing equipment may be modified, as desired, to accommodate the UV transparent materials 3, 4 and the template 2. Template 2 may also be configured for use with bulk semiconductor substrates other than wafers, for example silicon-on-insulator (SOI) substrates as exemplified by silicon-on-sapphire (SOS) substrates and silicon-on-glass (SOG) substrates. Template 2 is, further, not limited to use with semiconductor substrates comprising a silicon layer, but has utility with substrates of any semiconductor material or materials.

One of the UV transparent materials may have a pattern 6 formed on a surface thereof and is referred to herein as patterned UV transparent material 4. As described in more detail below, the other UV transparent material may provide mechanical integrity to the patterned UV transparent material 4 and is referred to herein as base UV transparent material 3. The template 2 may be formed from UV transparent materials to enable UV radiation to be transmitted through the template 2 during the imprinting process. Each of the base UV transparent material 3 and patterned UV transparent material 4 may be formed from a material that is substantially transparent to UV wavelength radiation including, hut not limited to, quartz, magnesium fluoride, a borosilicate glass, titanium oxide, calcium fluoride, silicon oxide, silicon dioxide, a polycarbonate material, a sapphire material, silicon germanium carbon, gallium nitride, silicon germanium, gallium arsenide, gate oxide, or combinations thereof. By way of non-limiting example, the borosilicate glass may be a PYREX® material or BOROFLOAT® 33 (“BF33”), which is a quartz material that includes greater than about 8% boric acid and no alkaline earth compounds, has a thermal expansion coefficient of 33×10⁻⁷ K⁻¹, and is available from Schott North America, Inc. (Elmsford, N.Y.). The material used for each of the base UV transparent material 3 and patterned UV transparent material 4 may be the same or different as long as the overall UV transparency of the template 2 is achieved.

The relative thicknesses of the base UV transparent material 3 and the patterned UV transparent material 4 may be different, with the base UV transparent material 3 having an increased thickness relative to that of the patterned UV transparent material 4. The base UV transparent material 3 may be thicker than the patterned UV transparent material 4 by a magnitude of from about five to about fifteen. In other words, base UV transparent material may be about five to about fifteen times thicker than then patterned UV transparent material. The thickness of the patterned UV transparent material 4 may range from about 250 μm to about 1000 μm, while the thickness of the base UV transparent material 3 may range from about 1250 μm to about 15000 μm. Together, the base UV transparent material 3, the patterned UV transparent material 4, and the UV transparent epoxy 5 may form the template 2 having a thickness of from about 1500 μm to about 17000 μm.

Since the patterned UV transparent material 4 may not possess sufficient mechanical strength and integrity to be used, by itself, as the imprint template, the patterned UV transparent material 4 may be joined or adhered to the base UV transparent material 3. The base UV transparent material 3 and the patterned UV transparent material 4 may be adhered by the UV transparent epoxy 5, providing additional mechanical integrity and strength to the patterned UV transparent material 4. The UV transparent epoxy 5 may be applied to a surface of at least one of the base UV transparent material 3 and the patterned UV transparent material 4 and cured to join these materials. The UV transparent epoxy 5 may be thermally cured or cured with UV radiation depending on the material selected. The UV transparent epoxy 5, before cure, may be of sufficient flexibility to provide increased physical contact between the UV transparent epoxy 5 and the base UV transparent material 3 and between the UV transparent epoxy 5 and the patterned UV transparent material 4. The UV transparent epoxy 5 may remain flexible after cure, or may become rigid after cure. The desired degree of flexibility of the UV transparent epoxy 5 may be affected by the bonding ability of the patterned UV transparent material 4 with the base UV transparent material 3, specifically the rigidity of the base UV transparent material 3. In addition, the bow and warp of the base UV transparent material 3 and the patterned UV transparent material 4 may affect the degree of rigidity or flexibility needed in the UV transparent epoxy 5. Depending on the material selected, a curing temperature for the UV transparent epoxy 5 may be determined by a person of ordinary skill in the art in accordance with the manufacturer's instructions. By way of non-limiting example, the UV transparent epoxy 5 may be UV cured at a temperature of from about room temperature to about 440° C.

In addition, the UV transparent epoxy 5 may have a minimal effect on the UV transparency of the template 2. In other words, using the UV transparent epoxy 5 in the template 2 may have substantially no effect on the UV transparency of the template 2. As such, the template 2 may exhibit a substantially uniform index of refraction throughout the thickness thereof. Depending on the material used as the UV transparent epoxy 5, the UV transparent epoxy 5 may be UV transparent before and after cure, or may be UV transparent after cure. The UV transparent epoxy 5 may also have a thermal expansion coefficient substantially similar to that of the base UV transparent material 3 and the patterned UV transparent material 4.

The UV transparent epoxy 5 may be applied to at least one of the base UV transparent material 3 and the patterned CV transparent material 4 by conventional techniques, such as by spin coating. Depending on the material used for the UV transparent epoxy 5, a suitable manner of application may be selected by a person of ordinary skill in the art. The UV transparent epoxy 5 may at least partially cover the surface of the at least one of the base UV transparent material 3 and the patterned UV transparent material 4. The viscosity and thickness of the UV transparent epoxy 5 may be selected to provide a sufficient degree of bonding between the UV transparent epoxy 5 and the base UV transparent material 3 and between the UV transparent epoxy 5 and the patterned UV transparent material 4. The viscosity of the UV transparent epoxy 5 may be within a range of from about 25,000 cps to about 50,000 cps at room temperature (about 25° C.). The thickness at which the UV transparent epoxy 5 is applied may depend on the planarities of the base UV transparent material 3 and the patterned UV transparent material 4. If the base UV transparent material 3 and the patterned UV transparent material 4 are substantially planar, the UV transparent epoxy 5 may be relatively thin, such as from about 2 μm to about 10 μm. However, if the base UV transparent material 3 and the patterned UV transparent material 4 have an increased surface roughness, the UV transparent epoxy 5 may be thicker, such as greater than or equal to about 20 μm.

By way of non-limiting example, the UV transparent epoxy 5 may be a polymeric, spin-on epoxy having stability to high temperatures, such as that sold under the WAFERBOND™ HT tradename. WAFERBOND™ HT products, such as WAFERBOND HT-250, are commercially available from Brewer Science, Inc. (Rolla, Mo.). By way of non-limiting example, the UV transparent epoxy 5 may be a high temperature, humidity resistant epoxy, such as EP30HT, which is commercially available from Master Bond, Inc. (Hackensack, N.J.). EP30HT is a two-part, amine-cured epoxy having a viscosity at room temperature of from about 35,000 cps to about 45,000 cps. EP30HT has a service temperature range of from about −60° F. to about 400° F. By way of non-limiting example, the UV transparent epoxy 5 may be EP-400, which is commercially available from Asahi Denka Kogyo K.K. (Tokyo, Japan).

In one embodiment, the base UV transparent material 3 is a conventional 0.25-inch (about 6350 μm) thick BF33 quartz wafer, the patterned UV transparent material 4 is a patterned, 500 μm thick quartz wafer, and the UV transparent epoxy 5 is WAFERBOND HT-250. However, other UV transparent materials may also be used. Direct bonding (without using the UV transparent epoxy 5) of the BF33 and the 500 μm thick quartz wafer is not effective because the stiffness of these materials prevents sufficient bonding. Without being bound by any theory, it is believed that the UV transparent epoxy 5 provides an additional degree of contact and flexibility between the base UV transparent material 3 and the patterned UV transparent material 4 for these materials to bond together.

Since the template 2 is transparent to UV radiation, an optically opaque material O may be deposited on the template 2 to form alignment marks 12 thereon, as shown in FIG. 2. The optically opaque material O may be chromium or chrome, polysilicon, a metal silicide, such as molybdenum silicide, tungsten silicide, or titanium silicide, or a metal, such as aluminum, tungsten, titanium, titanium nitride, tantalum, or tantalum nitride. The optically opaque material O may be deposited by conventional blanket deposition techniques, such as by coating or sputtering techniques. The optically opaque material O may be deposited on portions of the patterned UV transparent material 4 of the template 2, such as scribe areas or the periphery, where the alignment marks 12 are desired, the rest of the patterned UV transparent material 4 being masked to prevent such deposition. Alternatively, as described below, all of template 2 may be covered by the optically opaque material O. To provide proper alignment of the pattern 6 on the patterned UV transparent material 4, the alignment marks 12 may be formed before forming the pattern 6 in the patterned UV transparent material 4. The alignment marks 12 may also be used to align the template 2 with the substrate, which would typically include substrates on an unsingulated wafer, onto which the features corresponding to pattern 6 are to be formed.

The pattern 6 on the patterned UV transparent material 4, which may also be termed an “imprint pattern” for the sake of convenience, may include a topography having a plurality of recesses 8 and protrusions 10 of satisfactory size, configuration, and orientation in one surface of the patterned UV transparent material 4. The recesses 8 and protrusions 10 are ultimately used to produce substantially identical features on substrates fabricated on a wafer or other bulk semiconductor substrate contacted by the template 2. To form the pattern 6 in a UV transparent material and the alignment marks 12 in optically opaque material O, photolithographic techniques may be used. For instance, a photoresist material 14 may be formed on UV transparent material 4′, and patterned using a mask (not shown) having opaque and transparent openings in the desired pattern, as shown in FIG. 3. The photoresist material 14 may be formed from a conventional positive or negative photoresist material and may be deposited by conventional techniques, such as by spin coating. The opaque and transparent openings in the mask form a pattern that is complementary to the pattern 6 that is ultimately to be formed in the UV transparent material 4. The mask may be fabricated by conventional techniques and, therefore, is not described in detail herein. The mask may include, for example, a 4× pattern in that the pattern is four times the size of the pattern 6 to be formed in the UV transparent material 4 and four times the size of the features ultimately formed on the substrate. The photoresist material 14 may be exposed and developed, as known in the art, exposing selected portions of the UV transparent material 4′ to electromagnetic radiation. Exposure and development of the photoresist material 14 may be performed using conventional exposure equipment and developing solutions. Developing solutions for the photoresist material 14 may be selected by one of ordinary skill in the art and, therefore, are not discussed in detail herein. In addition to conventional photolithography, electron beam projection, electron beam direct write, ion direct write, or maskless lithography may be used to form the pattern 6 on the UV transparent material 4. The pattern in the photoresist material 14 may be then transferred to the UV transparent material 4′ and the alignment marks 12 formed in the optically opaque material O by etching. Two separate, selective etches may also be used, one for optically opaque material O and one for UV transparent material 4′, Depending on the material used, the UV transparent material 4, may be etched isotropically (wet etched) or anisotropically (dry etched). Wet and dry etching solutions for the UV transparent materials described above are known in the art and, therefore, are not discussed in detail herein. By way of non-limiting example, if the UV transparent layer 4′ is a quartz wafer, the quartz may be etched using a fluorine-based plasma etch. The fluorine-based plasma may include a fluorine-containing gas, such as CF₄, CHF₃, C₄F₈, SF₆, or combinations thereof, and an inert gas, such as argon, xenon, or combinations thereof.

Alternatively, the pattern 6 may be formed in the UV transparent material 4′ as illustrated in FIGS. 4 and 5. A chromium material 16, used as optically opaque material O, may be blanket deposited over the UV transparent material 4′ and the photoresist material 14 deposited over the chromium material 16, as shown in FIG. 4. The chromium material 16 may be deposited by conventional techniques and may range in thickness from about 80 nm to about 100 nm. While material 16 is described as being formed from chromium, material 16 may be formed from other metal materials that are opaque to the imaging wavelength and have significant etch selectivity relative to the UV transparent material 4′ including, but not limited to, chromium oxide, titanium, titanium nitride, tungsten, or combinations thereof. The photoresist material 14 may be a conventional photoresist material and may be deposited by conventional techniques, such as spin coating. The photoresist material 14 may be patterned as described above, to expose portions of the chromium material 16. As shown in FIG. 5, the pattern in the photoresist material 14 may be transferred to the chromium material 16 and, subsequently, to the UV transparent material 4′, by etching. For instance, the exposed portions of the chromium material 16 may be etched, using the photoresist material 14 as a mask. The remaining portions of the chromium material 16 may function as a hard mask for etching the UV transparent material 4′ and to provide alignment marks 12. Each of the chromium material 16 and the UV transparent material 4′ may be etched using a suitable, conventional wet or dry etch process. The etching solutions may be selected by one of ordinary skill in the art and, therefore, are not discussed in detail herein. As previously discussed, to form features having a high resolution on the substrate 18, which may be a wafer bearing a plurality of substrate locations thereon, the UV transparent material 4′ may be etched anisotropically, such as by using the fluorine-based plasma etch described above. Any portions of the photoresist material 14 and undesired portions of the chromium material 16 remaining on the UV transparent material 4′ after etching may be removed as desired, producing the pattern 6 and alignment marks 12 on the template 2, as shown in FIGS. 1 and 2.

While not illustrated, the pattern 6 may also be formed in the UV transparent material 4 by bonding the UV transparent material 4′ to the base UV transparent material 3 with the UV transparent epoxy 5, and then patterning the UV transparent material 4′. After bonding the UV transparent material 4′ and the base UV transparent material 3, the photoresist material 14 may be formed on the UV transparent material 4′ and patterned, as previously described in regard to FIG. 3, and this pattern transferred to the UV transparent material 4′. Alternatively, after bonding the UV transparent material 4′ and the base UV transparent material 3, the chromium material 16 and the photoresist material 14 may be formed on the UV transparent material 4′ and patterned, as previously described in regard to FIGS. 4 and 5, and this pattern transferred to the UV transparent material 4′. The pattern 6 may also be formed in the UV transparent material 4′ by conventional pitch doubling or pitch multiplication methods. Such methods are known in the art and, therefore, are not described in detail herein.

The template 2 shown in FIGS. 1 and 2 may be used directly in an imprint lithographic technique to imprint the pattern 6 on the substrate 18 of like size, forming corresponding features on the substrate 18. Likewise, template 2 may be used directly in an imprint lithographic technique to imprint the pattern 6 on a subsequent template. The features to be formed on the substrates 18 may be a negative image (reversed image) of the pattern 6 on the template 2. Alternatively, the template 2 may be divided, such as by dicing, to form smaller templates that are used in imprint lithography or smaller groups of substrates. The pattern 6 on each of the smaller templates may be the same or different. The template 2 on each of the divided templates may be bonded to the optional second UV transparent material before or after dicing.

To form the desired features on the substrate 18 by imprint lithography, the template 2 having the pattern 6 may be brought into contact with the substrate 18. A complete process flow for fabricating the substrate 18 is not described herein. However, the remainder of the process flow is known to a person of ordinary skill in the art. Accordingly, only the process steps necessary to understand the invention are described herein. As shown in FIG. 6, substrate 18 may include a semiconductor substrate 20 and additional layers thereon, such as metal layers, oxide layers, carbon hard mask layers, or polysilicon layers. The substrate 18 may also include trenches or diffusion regions. For the sake of clarity, the additional layers, trenches, and diffusion regions are not shown in FIG. 6. The semiconductor substrate 20 may be a conventional substrate or other bulk substrate including a semiconductive material. As used herein, the term “semiconductor substrate” includes not only silicon wafers, but also silicon-on-insulator (“SOI”) substrates, silicon-on-sapphire (“SOS”) substrates, epitaxial layers of silicon on a base semiconductor foundation, and other semiconductor, or optoelectronics materials, such as silicon-germanium, germanium, gallium arsenide, or indium phosphide.

The substrate 18 may also include a transfer material 22 that is deformable under applied pressure and does not adhere to a surface of the template 2, especially as the template 2 is removed from the substrate 18. Since the transfer material 22 is deformable, the transfer material 22 may fill the recesses 8 in the pattern 6 when the template 2 and the substrate 18 come into contact. The transfer material 22 may be a radiation sensitive material including, but not limited to, a photocurable or photosensitive material, such as a photoresist material. The transfer material 22 may be sensitive to UV light, visible light, infrared light, actinic light, or other radiation sources, such as electron beams or x-rays. Materials that may b used as the transfer material 22 are known in the art. For the sake of example only, the transfer material 22 may be formed from a conventional photoresist material that is curable by exposure to UV light, such as a curable organosilicon material.

The substrate 18 and the template 2 may be maintained substantially parallel, and in close proximity, to one another. The substrate 18 and the template 2 may then be contacted with minimal pressure so that the transfer material 22 deforms into the pattern 6 of the template 2. As shown in FIG. 7, the substrate 18′ may thus be provided with a negative image 24 (reversed image) of the pattern 6 in its imprinted transfer material 22. If the transfer material 22 is a radiation-sensitive material, the transfer material 22 may subsequently be exposed to radiation, such as UV radiation. Since the template 2 is UV transparent, the UV radiation is transmitted through the template 2 from the back, unpatterned surface thereof to harden portions of the negative image 24 of transfer material 22 that include photoresist material filling recesses 8 of pattern 6 or to harden all of the negative image 24 of transfer material 22 that includes photoresist material filling recesses 8 and protrusions 10 of pattern 6. Alternatively, if the transfer material 22 includes a material that is sensitive to heat, pressure, or combinations thereof, which are generated by contacting the template 2 with the substrate 18, the heat, pressure, or combinations thereof may be used to cure, harden, or solidify the transfer material 22. The template 2 may then be removed from the substrate 18. The template 2 and the substrate 18 may be separated without damaging, or otherwise adversely affecting, the negative image 24. For instance, the template 2 may be treated with a material that lowers the surface energy of the template 2, as known in the art, to assist in separating the template 2 from the substrate 18 without damage to the imprinted, exposed negative image 24.

The negative image 24 in the transfer material 22 may be transferred to the semiconductor substrate 20 or underlying materials of the substrate 18′ using the transfer material 22 as a mask. For instance, the negative image 24 may be transferred into the semiconductor substrate 20 or into the metal, carbon, hard mask layer, oxide, or polysilicon layers (not shown) previously formed on the semiconductor substrate 20 by dry etching or wet etching. Any remaining portions of the transfer material 22 may then be removed, providing the features 26 on the substrate 18″ as shown in FIG. 8. The features 26 may be substantially the same size, configuration, and orientation as the dimensions of the pattern 6 on the template 2. Since the pattern 6 is formed by photolithography, the feature sizes may be determined by the resolution of the photolithogaphic techniques used to form the pattern 6. In one embodiment, the features 26 have a feature size of less than about 100 nm, such as less than about 45 nm. Alternatively, the negative image 24 in the transfer material 22 may be subjected to ion implantation to form implanted regions on the substrate 18″.

In addition to forming features 26 on the substrate 18′, the template 2 may be used as a master template to create at least one daughter template. To form the daughter template, the pattern 6 on the template 2 may be transferred to an additional structure (not shown), which includes a UV transparent material and a transfer material, such as a photoresist material. The UV transparent material and transfer material of the structure that is ultimately to become the daughter template may be one of the materials described above. The transfer material may be deformable under pressure so that when the template 2 contacts the transfer material of the structure that is ultimately to be the daughter template, the pattern 6 of the master template is transferred to the transfer material. The pattern in the transfer material may subsequently be etched into the UV transparent material, producing the daughter template. The pattern on each of the daughter templates may be the reverse of the pattern 6 on the master template. In other words, the pattern 6 on the master template may be a negative image of the pattern on the daughter template.

Since the template 2 contacts the substrate 18 or other structure that is ultimately to become the daughter template during imprint lithography, the template 2 may become easily damaged. Therefore, the master template may be stored and preserved while one of the daughter templates fabricated from it is used to imprint the features on the substrate 18. If the daughter template is damaged during imprinting, another daughter template may be used to imprint the features or the master template may be used to create additional daughter templates.

The template 2 produced by the methods of the invention provides numerous advantages. In forming the substrate 18″, if imprint lithography is used at some process levels and conventional photolithography is used at other process levels, lens distortion and magnification factor effects are typically observed in the substrate 18″. However, the template 2 formed by the methods of the invention may be used to provide improved matching between the imprint lithography process levels and the conventional photolithography process levels. For instance, if the same photostepper used in the process levels formed by conventional photolithography is also used to for the template 2, the lens distortion and magnification factor effects at the different process levels in the substrate 18″ may be minimized. The method of the invention may also provide the template 2 at a reduced cost compared to conventional techniques. In addition, use of the UV transparent epoxy 5 to join together base UV transparent material 3 and patterned UV transparent material 4 enables bonding of materials that previously could not be adequately bonded. In addition, since the UV transparent epoxy 5 is suitable for use within a wide temperature range, the base UV transparent material 3 and the patterned UV transparent material 4 may be bonded to form the template 2 without restrictions on the formation temperature.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the scope of the invention as defined by the following appended claims and their legal equivalents.

What is claimed is:

1. A template for use in imprint lithography, comprising:
a patterned ultraviolet transparent material in contact with an ultraviolet transparent epoxy; and
a base ultraviolet transparent material in contact with the ultraviolet transparent epoxy.

2. The template of claim 1, wherein the template comprises a substantially uniform index of refraction.

3. The template of claim 1, wherein a thickness of the base ultraviolet transparent material is greater than a thickness of the patterned ultraviolet transparent material by a magnitude of from about 5 to about 15.

4. The template of claim 1, wherein the patterned ultraviolet transparent material comprises a thickness of from about 250 μm to about 1000 μm.

5. The template of claim 1, wherein the base ultraviolet transparent material comprises a thickness of from about 1250 μm to about 15000 μm

6. The template of claim 1, wherein the patterned ultraviolet transparent material and the base ultraviolet transparent material are of substantially the same size and shape.

7. The template of claim 1, wherein the ultraviolet transparent epoxy comprises a polymeric, spin-on epoxy.

8. The template of claim 1, wherein the ultraviolet transparent epoxy comprises a two-part, amine-cured epoxy having a viscosity at room temperature of from about 35,000 cps to about 45,000 cps.

9. The template of claim 1, wherein the patterned ultraviolet transparent material and the base ultraviolet transparent material are adhered to one another by the ultraviolet transparent epoxy.

10. A template for use in imprint lithography, comprising:
a base ultraviolet transparent material and a patterned ultraviolet transparent material bonded together by an ultraviolet transparent epoxy, wherein the base ultraviolet transparent material and the patterned ultraviolet transparent material are of substantially the same size and shape.

11. A template for use in imprint lithography, comprising:
a patterned ultraviolet transparent material bonded to a first surface of an ultraviolet transparent epoxy; and
a base ultraviolet transparent material bonded to a second surface of the ultraviolet transparent epoxy,
wherein the ultraviolet transparent epoxy, the patterned ultraviolet transparent material, and the base ultraviolet transparent material have substantially similar ultraviolet transparencies.

12. A method of forming a template for use in imprint lithography, comprising:
forming a pattern in an ultraviolet transparent material;
applying an ultraviolet transparent epoxy to the ultraviolet transparent material;
placing a base ultraviolet transparent material in contact with the ultraviolet transparent epoxy; and
curing the ultraviolet transparent epoxy to bond the ultraviolet transparent material and the base ultraviolet transparent material thereto.

13. The method of claim 12, wherein forming a pattern in an ultraviolet transparent material comprises forming the pattern in a material selected from the group consisting of quartz, magnesium fluoride, titanium oxide, calcium fluoride, a borosilicate glass, silicon oxide, silicon dioxide, polycarbonate, sapphire, silicon germanium carbon, gallium nitride, silicon germanium, gallium arsenide, gate oxide, and combinations thereof.

14. The method of claim 12, wherein forming a pattern in an ultraviolet transparent material comprises forming a photoresist material over the ultraviolet transparent material, forming a pattern in the photoresist material, and transferring the pattern from the photoresist material to the ultraviolet transparent material.

15. The method of claim 14, wherein transferring the pattern from the photoresist material to the ultraviolet transparent material comprises anisotropically etching the pattern into the ultraviolet transparent material.

16. The method of claim 14, wherein transferring the pattern from the photoresist material to the ultraviolet transparent material comprises isotropically etching the pattern into the ultraviolet transparent material.

17. The method of claim 12, wherein forming a pattern in an ultraviolet transparent material comprises forming the pattern having at least one feature dimension of less than about 100 nm in the ultraviolet transparent material.

18. The method of claim 12, wherein forming a pattern in an ultraviolet transparent material comprises forming the pattern having at least one feature dimension of less than about 45 nm in the ultraviolet transparent material.

19. The method of claim 12, wherein forming a pattern in the ultraviolet transparent material comprises forming the pattern by electron beam projection, electron beam direct write, ion direct write, photolithography, or maskless lithography.

20. The method of claim 12, wherein placing a base ultraviolet transparent material in contact with the ultraviolet transparent epoxy comprises forming the base ultraviolet transparent material having a thickness greater than the thickness of the ultraviolet transparent material by a magnitude of from about 5 to about 15.

21. The method of claim 12, wherein placing a base ultraviolet transparent material in contact with the ultraviolet transparent epoxy comprises forming the base ultraviolet transparent material from a material selected from the group consisting of quartz, magnesium fluoride, titanium oxide, calcium fluoride, a borosilicate glass, silicon oxide, silicon dioxide, polycarbonate, sapphire, silicon germanium carbon, gallium nitride, silicon germanium, gallium arsenide, gate oxide, and combinations thereof.

22. The method of claim 12, wherein applying an ultraviolet transparent epoxy to the ultraviolet transparent material comprises applying the ultraviolet transparent epoxy having an index of refraction substantially similar to an index of refraction of each of the ultraviolet transparent material and the base ultraviolet transparent material.

23. The method of claim 12, wherein applying an ultraviolet transparent epoxy to the ultraviolet transparent material comprises applying the ultraviolet transparent epoxy at a thickness of between about 5 μm and about 10 μm.

24. A method of imprinting features on a substrate, comprising:
contacting a substrate with an imprint template, the imprint template comprising:
a patterned ultraviolet transparent material bonded to an ultraviolet transparent epoxy; and
a base ultraviolet transparent material bonded to the ultraviolet transparent epoxy;
transferring a pattern of the patterned ultraviolet transparent material into a transfer material on the substrate; and
transferring the pattern into a semiconductor substrate underlying the transfer material to form features on the semiconductor substrate.

25. The method of claim 24, wherein transferring the pattern into a semiconductor substrate underlying the transfer material to form features on the semiconductor substrate comprises forming features having a dimension of less than about 45 nm in the semiconductor substrate.
